(19) United States
(12) Patent Application Publication
(10) Pub. No.: US 2026/0164945 A1
(43) Pub. Date: Jun. 11, 2026

(54) DISPLAY PANEL AND DISPLAY DEVICE

(71) Applicants: Hefei Visionox Technology Co., Ltd., Hefei (CN); Visionox Technology Inc., Kunshan (CN); Hefei Visionox Electronics Co., Ltd., Hefei (CN)

(72) Inventors: Zhiwei ZHOU, Hefei (CN); Bing HAN, Hefei (CN); Tian WANG, Hefei (CN)

(73) Assignees: Hefei Visionox Technology Co., Ltd., Hefei (CN); Visionox Technology Inc., Kunshan (CN); Hefei Visionox Electronics Co., Ltd., Hefei (CN)

(21) Appl. No.: 19/430,159

(22) Filed: Dec. 22, 2025

Related U.S. Application Data
(63) Continuation of application No. PCT/CN2025/132914, filed on Nov. 6, 2025.

(30) Foreign Application Priority Data
Dec. 10, 2024 (CN) 202411832203.7

(51) Int. Cl. H10K 59/122; H10K 59/35

(52) U.S. Cl. CPC H10K 59/122; H10K 59/352; H10K 59/353

(57) ABSTRACT

The present disclosure provides a display panel and a display device. The display panel includes a base plate, and an isolation structure provided with a plurality of isolation openings, a pixel-defining layer provided with a plurality of pixel openings and a plurality of light-emitting units disposed on the base plate. The plurality of light-emitting units include a first-type light-emitting unit and a second-type light-emitting unit. A ratio of an area of an orthographic projection of the pixel opening corresponding to the light-emitting unit on the base plate to an area of an orthographic projection of the isolation opening corresponding to the light-emitting unit on the base plate is referred to as a first ratio. The first ratio corresponding to the first-type light-emitting units is less than the first ratio corresponding to the second-type light-emitting units to adjust an aperture ratio of the display panel.

### CROSS-REFERENCE TO RELATED APPLICATIONS

This application is a continuation of International Application No. PCT/CN2025/132914, filed on Nov. 6, 2025, which claims priority to Chinese Patent Application No. 2024118322037, filed on Dec. 10, 2024. The disclosures of the aforementioned applications are hereby incorporated by reference in their entireties.

### FIELD

The present disclosure generally relates to the field of display technologies, and in particular, to a display panel and a display device.

### BACKGROUND

An Organic Light Emitting Diode (OLED) is an organic thin-film electroluminescent unit, which has garnered significant attention and found widespread application in electronic display products due to their advantages, including simple fabrication processes, low cost, low power consumption, high brightness, wide viewing angles, high contrast ratios, and the ability to achieve flexible displays. In a preparation process of traditional display panels, technology of fine metal mask (FMM) is typically used to pattern light-emitting pixels. FMM technology is mature and has extensive mass production experience. However, FMM technology also suffers from limitations such as restricted precision, high development costs, and lengthy development cycles. The fine metal mask-free technology eliminates the constraints imposed by traditional OLED processes on display size, resolution, and other screen performance characteristics, offering advantages such as high performance, full-area sizing, and agile delivery. Patents CN118251982A, CN116648095A, CN117062489A, CN118742138A, CN118678783A, CN118660598A, CN118675450A, CN118824188A, and CN118781966A document relevant content of fine metal mask-free technology for reference.

However, current electronic display products are constrained by their structural design, making it difficult to further enhance the display performance of the display panels.

### SUMMARY

In a first aspect, the present disclosure provides a display panel. The display panel includes a base plate, an isolation structure disposed on the base plate, a pixel defining layer, and a plurality of light-emitting units. The pixel defining layer is disposed on a side of the base plate and provided with a plurality of pixel openings. The isolation structure is located on ta side, facing away from the base plate, of the pixel defining layer, and a plurality of isolation openings are defined by the isolation structure. The plurality of isolation openings are respectively in communication with corresponding pixel openings. At least part of a light-emitting unit is located in the isolation opening, and the plurality of light-emitting units include a first-type light-emitting unit and a second-type light-emitting unit. A ratio of an area of an orthographic projection of the pixel opening corresponding to the light-emitting unit on the base plate to an area of an orthographic projection of the isolation opening corresponding to the light-emitting unit on the base plate is referred to as a first ratio. The first ratio corresponding to the first-type light-emitting units is less than the first ratio corresponding to the second-type light-emitting units.

In a second aspect, the present disclosure provides a display panel including a base plate and, an isolation structure, a pixel defining layer, and a plurality of light-emitting units disposed on the base plate. The pixel defining layer is disposed on a side of the base plate and provided with a plurality of pixel openings. The isolation structure is disposed on a side, facing away from the base plate, of the pixel defining layer, and a plurality of isolation openings are defined by the isolation structure. The plurality of isolation openings are respectively in communication with corresponding pixel openings. At least part of a light-emitting unit is located in the isolation opening, and the plurality of light-emitting units comprise a first-color light-emitting unit and a second-type light-emitting unit. An area of the pixel opening corresponding to the first-color light-emitting unit is smaller than an area of the pixel opening corresponding to the second-color light-emitting unit. A ratio of an area of an orthographic projection of the pixel opening corresponding to the first-color light-emitting unit on the base plate to an area of an orthographic projection of a corresponding isolation opening on the base plate is less than a ratio of an area of an orthographic projection of the pixel opening corresponding to the second-color light-emitting unit on the base plate to an area of an orthographic projection of a corresponding isolation opening on the base plate.

In a third aspect, the present disclosure provides a display panel including a base plate, an isolation structure, a pixel defining layer, and a plurality of light-emitting units disposed on the base plate. The pixel defining layer is located on one side of the base plate and is provided with a plurality of pixel openings. The isolation structure is located on a side, facing away from the base plate, of the pixel defining layer, and a plurality of isolation openings are defined by the isolation structure. The plurality of isolation openings are respectively in communication with corresponding pixel openings. At least part of a light-emitting unit is located in the isolation opening, and the plurality of light-emitting units comprise a first-type light-emitting unit and a second-type light-emitting unit. A perimeter of an orthographic projection of the pixel opening corresponding to the light-emitting unit on the base plate is less than a perimeter of an orthographic projection of the isolation opening corresponding to the light-emitting unit on the base plate, and a ratio of the perimeter of the orthographic projection of the pixel opening corresponding to the light-emitting unit on the base plate to the perimeter of the orthographic projection of the corresponding isolation opening on the base plate is referred to as a second ratio. The second ratio corresponding to the first-type light-emitting unit is less than the second ratio corresponding to the second-type light-emitting unit.

### BRIEF DESCRIPTION OF THE DRAWINGS

FIG. 1 is a schematic diagram of the planar structure of a display panel provided by an embodiment of the present disclosure.

FIG. 2 is an enlarged view of region S1 of the display panel shown in FIG. 1.

FIG. 3 is an enlarged view of a portion of the display panel shown in FIG. 2.

FIG. 4 is a cross-sectional view of the display panel shown in FIG. 2 along line M-N.

FIG. 5 is an enlarged view of the pixel structure of a portion of the display panel provided by an embodiment of the present disclosure.

FIG. 6 is a plan schematic diagram of a pixel arrangement suitable for the pixel structure shown in FIG. 5.

FIG. 7 is a plan schematic diagram of a pixel arrangement method for a display panel provided by an embodiment of the present disclosure.

FIG. 8 is a plan schematic diagram of a pixel arrangement method for a display panel provided by an embodiment of the present disclosure.

FIG. 9 is a plan schematic diagram of a pixel arrangement method for a display panel provided by an embodiment of the present disclosure.

FIG. 10 is a plan schematic diagram of a pixel arrangement method for a display panel provided by an embodiment of the present disclosure.

FIG. 11 is a plan view of a pixel arrangement of a display panel provided by an embodiment of the present disclosure.

FIG. 12 is a plan view schematic diagram of a pixel arrangement method for a display panel provided by an embodiment of the present disclosure.

FIG. 13 is a cross-sectional view of a display panel provided by an embodiment of the present disclosure.

FIG. 14 is a cross-sectional view of a display panel provided by an embodiment of the present disclosure.

FIGS. 15A to 15F are process diagrams illustrating a preparation method for forming a display panel as shown in FIG. 14, provided by an embodiment of the present disclosure.

FIG. 16 is a schematic diagram showing the positional relationship between a partial film layer of a display panel provided by an embodiment of the present disclosure and a deposition source during deposition.

FIG. 17 is a cross-sectional view of a portion of a display panel provided by an embodiment of the present disclosure.

### DETAILED DESCRIPTION OF THE EMBODIMENTS

A clear and complete description of the embodiments of the specification will be provided with reference to accompanying drawings in the following. It should be understood that the described embodiments represent only a part of the embodiments disclosed herein, not the entirety.

In display products, certain functional film layers within light-emitting units are formed via vapor deposition. Each light-emitting unit includes a plurality of functional film layers, and materials of some functional film layers (such as light-emitting layers) in the light-emitting units that emit light with different wavelengths are different. Different light-emitting materials exhibit varying lifespans and luminous efficiencies, potentially causing display color deviation issues. Simultaneously, when depositing these functional layers using a mask (e.g., a fine mask), a plurality of alignment steps are required. To address positional shifts caused by alignment accuracy errors, sufficient space (a safety margin related to alignment error) must be reserved between different light-emitting units. This ensures an actual light-emitting area of the units overlaps sufficiently with their designed positions (design area). This effectively reduces the design area of the light-emitting region, limiting both the light-emitting area and a density of the light-emitting units. Consequently, pixels per inch (PPI) of the display panel may be difficult to be increased.

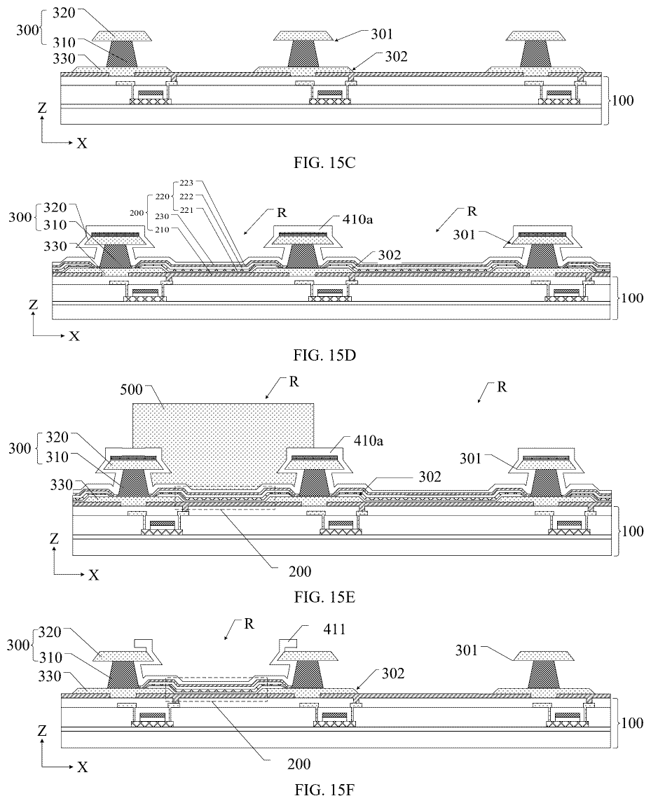

In the present disclosure, an isolation structure is provided at intervals between light-emitting units to disconnect the functional film layers of adjacent units. Consequently, during a deposition process of the functional film layer, full-surface deposition may be performed on the display panel without the need for individual mask-based preparation of the functional film layer for each light-emitting unit. This process eliminates the need for alignment precision during deposition, enabling smaller intervals between light-emitting units to increase the PPI (the underlying principle will be described in relevant embodiments shown in FIGS. 15A to 15F below).

The distribution of the light-emitting units is constrained by the isolation structure, which limits the position and area of the light-emitting regions, thereby affecting an aperture ratio of the display panel. Furthermore, the isolation structure at least acts as a barrier during the preparation process of light-emitting unit, resulting in lower connection quality at the interface between the light-emitting unit and the isolation structure. This creates higher impedance. If impedance becomes excessively high, voltage distribution imbalances (e.g., excessive voltage drop) may occur during light-emitting unit drive, not only increasing power consumption but also impairing visual performance of the display panel.

Below, the structure of the display panel according to at least one embodiment of the present disclosure will be described in detail with reference to the accompanying drawings. Furthermore, in these drawings, a spatial rectangular coordinate system is established with the base plate as a reference plane to more intuitively present the relative positions of relevant structures within the display panel. Within this spatial rectangular coordinate system, the X-axis and Y-axis are parallel to the plane located by the base plate, while the Z-axis is perpendicular to the plane located by the base plate.

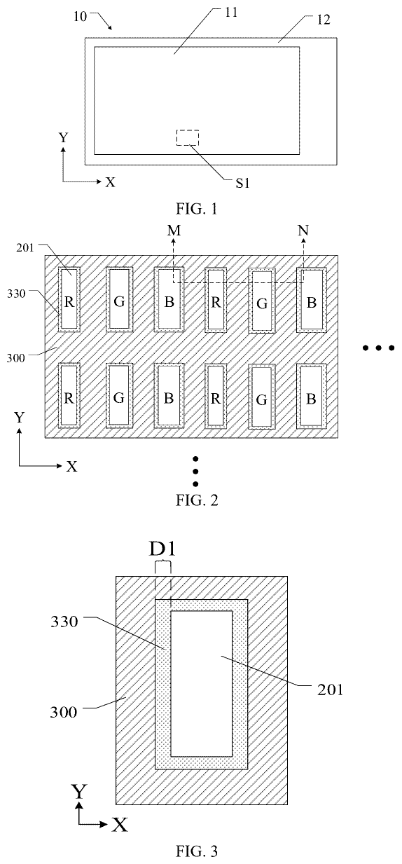

As shown in FIGS. 1 to 4, a planar region of the display panel 10 may be divided into a display region 11 and a frame region 12 surrounding the display region 11. The display region 11 may be arranged with sub-pixels (also referred to as subpixels, etc.), such as R, G, and B sub-pixels. A physical structure of the sub-pixels may be a light-emitting unit. Adjacent sub-pixels emitting light of different colors form a pixel (also referred to as a pixel unit or macro pixel). A density of these pixels within the display region 11 represents the PPI. In some embodiments of the present disclosure, a part of wiring lines in the frame region 12 may be arranged within the display region 11, thereby enabling the frame region 12 to be designed as a single-sided frame.

A physical structure of the display panel 10 may include a base plate 100, a display function layer disposed on the base plate, a pixel defining layer 330, and an isolation structure 300. The display function layer may include a plurality of light-emitting units 200.

The pixel defining layer 330 is located on a side of the base plate 100 and is provided with a plurality of pixel openings 302. The pixel plurality of openings 302 correspond to the plurality of light-emitting units 200 to define light-emitting regions 201 of the plurality of light-emitting units 200. That is, a part of the light-emitting unit 200 exposed by the pixel opening 302 may be used for light emission, and the light-emitting region 201 is an area where a part of the light-emitting unit 200 capable of exciting light is located.

The isolation structure 300 is disposed on a side, facing away from the base plate 100, of the pixel defining layer 330 and a plurality of isolation openings 301 are defined by the isolation structure 300. That is, a planar shape of the isolation structure 300 exhibits a grid-like pattern, with the plurality of isolation openings 301 forming mesh holes of this grid pattern. The plurality of isolation openings 301 are respectively in communication with corresponding pixel openings 302.

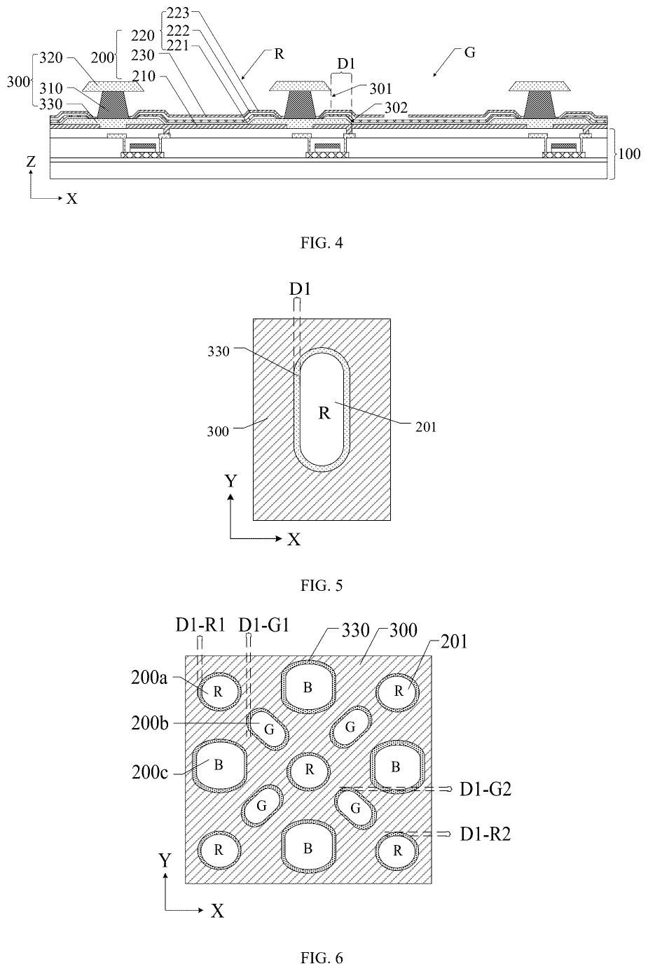

In some embodiments of the present disclosure, the isolation opening 301 corresponds to the pixel opening 302 in one-to-one correspondence, as shown in FIGS. 3 and 4; alternatively, in other embodiments of the present disclosure, an isolation opening 301 may include a plurality of pixel openings 302, with the plurality of pixel openings 302 collectively forming the light-emitting region 201 of the light-emitting unit 200. A structure of the display panel of the present disclosure will be described below using an example where one pixel opening 302 is provided within an isolation opening 301.

The light-emitting unit 200 is formed using the isolation structure 300. Therefore, at least part of the light-emitting unit 200 is located within the isolation opening 301. Furthermore, a ratio of an area of an orthographic projection of the pixel opening 302 on the base plate 100 to an area of an orthographic projection of a corresponding isolation opening 301 on the base plate 100 is referred to as a first ratio. The light-emitting unit 200 includes a first-type light-emitting unit 200a and a second-type light-emitting unit 200b. The first ratio corresponding to the first-type light-emitting unit 200a is less than the first ratio corresponding to the second-type light-emitting unit 200b. For example, a color of light emitted by the first-type light-emitting unit 200a is different from a color of light emitted by the second-type light-emitting unit 200b. Thus, by setting different first ratios between different light-emitting units 200, an area proportion of their light-emitting regions 201 can be adjusted based on types of the light-emitting units 200, thereby regulating an aperture ratio of the display panel, balancing deviations in lifespan and luminous efficiency caused by different light-emitting materials, and further improving the display effect. Additionally, this approach can adjust a contact area between different types of light-emitting units 200 (e.g., the first-type light-emitting unit 200a and the second-type light-emitting unit 200b) and the isolation structure 300, thereby adjusting the impedance between different types of light-emitting units 200 and the isolation structure 300, addressing the issue of uneven voltage drop distribution during operation, and further improving the display performance of the display panel.

The orthographic projection of the pixel opening 302 on the base plate 100 is located within the orthographic projection of the corresponding isolation opening 301 on the base plate 100. The light-emitting unit 200 includes a first electrode 210, a light-emitting function layer 220, and a second electrode 230. The light-emitting function layer 220 and the second electrode 230 are disposed within the pixel opening 302 and extend to a part of a surface, facing away from the base plate 100, of the pixel defining layer 330 to connect with the isolation structure 300. The isolation opening 301 and the pixel opening 302 jointly define positions of the light-emitting function layer 220 and the second electrode 230 within the light-emitting unit 200. Within the isolation opening 301, the orthographic projection of the pixel opening 302 on the base plate 100 coincides with the light-emitting region 201. This alignment ensures that the pixel opening 302 is fully coincident within the light-emitting region 201, that is, the light-emitting region 201 of light-emitting device 200 is defined by the pixel defining layer 330.

In at least one embodiment of the present disclosure, areas of pixel openings 302 corresponding to at least two types of the light-emitting units 200 (e.g., corresponding to R sub-pixels and G sub-pixels) are unequal. The first ratio corresponding to the light-emitting unit 200 in correspondence to a larger pixel opening 302 (e.g., corresponding to the G sub-pixel) is greater than the first ratio corresponding to the light-emitting unit 200 in correspondence to a smaller pixel opening 302 (e.g., corresponding to the G sub-pixel). For example, an area of an orthographic projection of the pixel opening 302 corresponding to the first-type light-emitting unit 200a (e.g., corresponding to the R sub-pixel) on the base plate 100 is smaller than an area of an orthographic projection of the pixel opening 302 corresponding to the second-type light-emitting unit 200b (e.g., corresponding to the G sub-pixel) on the base plate 100. In the display region, the area of the orthographic projection of each pixel opening 302 corresponding to the first-type light-emitting units 200a (e.g., corresponding to R sub-pixels) on the base plate 100 is less than the area of the orthographic projection of each pixel opening 302 corresponding to the second-type light-emitting units 200b (e.g., corresponding to G sub-pixels) on the base plate 100. Thus, a proportion of light-emitting units 200 with larger light-emitting areas 201 (e.g., corresponding to G sub-pixels) may be further increased, thereby increasing the aperture ratio of the display panel, balancing luminous efficiency and lifespan of the light-emitting units 200, and improving the display performance of the display panel. Additionally, the light-emitting units 200 with larger light-emitting areas 201 (e.g., corresponding to G sub-pixels) may have a larger contact area (considered as a sum of lengths) with the isolation structure 300. Compared with light-emitting units 200 with smaller light-emitting areas 201 (e.g., corresponding to R sub-pixels), when the proportion of the light-emitting units 200 with larger light-emitting areas 201 (e.g., corresponding to G sub-pixels) increases, a total contact area between all light-emitting units 200 and the isolation structure 300 increases significantly, thereby reducing the impedance between the light-emitting units 200 and the isolation structure 300, and improving the display performance of the display panel.

In at least one embodiment of the present disclosure, as shown in FIGS. 5 and 6, a wavelength of light emitted by the first-type light-emitting unit 200a is greater than a wavelength of light emitted by the second-type light-emitting unit 200b. For example, the first-type light-emitting unit 200a and the second-type light-emitting unit 200b may sequentially emit red light and green light (as shown in the figures), or they may sequentially emit green light and blue light (not shown in the figures).

In at least one embodiment of the present disclosure, as shown in FIGS. 5 and 6, the light-emitting unit 200 may further include a third-type light-emitting unit 200c. The area of the orthographic projection of the pixel opening 302 corresponding to the second type light-emitting unit 200b on the base plate 100 is smaller than an area of an orthographic projection of the pixel opening 302 corresponding to the third type light-emitting unit 200c on the base plate 100. Meanwhile, the first ratio corresponding to the second type light-emitting unit 200b is less than the first ratio corresponding to the third type light-emitting unit 200c. For example, areas of the pixel openings 302 corresponding to the first-type light-emitting unit 200a, the second-type light-emitting unit 200b, and the third-type light-emitting unit 200c increase sequentially, and the first ratios corresponding to the first-type light-emitting unit 200a, the second-type light-emitting unit 200b, and the third-type light-emitting unit 200c also increase sequentially.

In some embodiments of the present disclosure, the lower the luminous efficiency of the light-emitting unit 200 is, the larger the area of the orthographic projection of the pixel opening 302 on the base plate 100. For example, if the luminous efficiency of the first type light-emitting unit 200a, the second-type light-emitting unit 200b, and the third-type light-emitting unit 200c decrease in order, then areas of orthographic projections of the corresponding pixel openings 302 on the base plate 100 increases in order, and the first ratios corresponding to the first-type light-emitting unit 200a, the second-type light-emitting unit 200b, and the third-type light-emitting unit 200c also increases in order. In one embodiment, the first-type light-emitting unit 200a, the second-type light-emitting unit 200b, and the third-type light-emitting unit 200c may respectively be a red light-emitting unit (R), a green light-emitting unit (G), and a blue light-emitting unit (B), with the specific colors determined based on the luminous efficiency. For example, the first-type light-emitting unit 200a, the second-type light-emitting unit 200a, and the third-type light-emitting unit 200c may sequentially be the red light-emitting unit, the green light-emitting unit, and the blue light-emitting unit, respectively; or the first-type light-emitting unit 200a, the second-type light-emitting unit 200b, and the third-type light-emitting unit 200c may sequentially be the blue light-emitting unit, the red light-emitting unit, and the green light-emitting unit, respectively; or the first-type light-emitting unit 200a, the second-type light-emitting unit 200b, and the third-type light-emitting unit 200c may sequentially be the green light-emitting unit, the red light-emitting unit, and the blue light-emitting unit, respectively.

In some embodiments of the present disclosure, referring again to FIGS. 3 and 4, the wavelengths of light emitted by the first-type light-emitting unit 200, the second-type light-emitting unit 200, and the third-type light-emitting unit 200 decrease sequentially. For example, the first-type light-emitting unit 200, the second-type light-emitting unit 200, and the third-type light-emitting unit 200 sequentially emit red light, green light, and blue light.

In other embodiments of the present disclosure, the wavelengths of light emitted by the second-type light-emitting unit, the first-type light-emitting unit, and the third-type light-emitting unit decrease sequentially. For example, the first-type light-emitting unit, the second-type light-emitting unit, and the third-type light-emitting unit sequentially emit green light, red light, and blue light.

In embodiments of the present disclosure, a numerical range of the first ratio is not restricted and may be designed according to requirements of an actual process. For example, in at least one embodiment of the present disclosure, the first ratio may range from 0.2 to 0.9. The first ratio may be 0.2, 0.3, 45 0.4, 0.5, 0.6, 0.7, 0.8, or 0.9, etc. Furthermore, the first ratio corresponding to the light-emitting unit corresponding to the pixel opening 302 with the largest area (e.g., the third type light-emitting unit 200) ranges from 0.5 to 0.9.

As shown in FIG. 6, the first ratios corresponding to different isolation openings 301 may be set to be substantially equal (including cases where they are completely equal). That is, a distance D1 between an orthographic projection of an edge of the pixel opening 302 of the light-emitting unit 200 (e.g., the edge of the pixel opening 302) on the base plate 100 and an orthographic projection of a corresponding edge of the isolation opening 301 on the base plate 100 is referred to as a first distance. In a direction parallel to a plane located by the base plate 100 (e.g., a first direction), a ratio between first distances corresponding to the light-emitting units 200 with the pixel openings 302 of different areas at the same side ranges from 0.9 to 1.1, such as 0.9, 0.95, 1.0, 1.05, or 1.1. For example, the first distances corresponding to the light-emitting units 200 with the pixel openings 302 of different areas at the same side may be equal. For example, the first direction may be parallel to the plane defined by base plate 100, and further, the first direction may be parallel to the X-axis. For example, the pixel openings 302 (or isolation openings 301) corresponding to the first-type light-emitting unit 200a and the second-type light-emitting unit 200b have unequal areas. However, along the first direction (e.g., the direction of the X-axis), the first distance (D1-R1) corresponding to the first-type light-emitting unit 200a and the first distance (D1-G1) corresponding to the second-type light-emitting unit 200b are equal. That is, along the X-axis direction, the first distance corresponding to the first-type light-emitting unit 200 a at a left side is equal to or substantially equal (with a ratio of 0.9-1.1) to the first distance corresponding to the second-type light-emitting unit 200b at the left side. This facilitates the design of parameters for each light-emitting unit 200 and its adjacent structures, such as the isolation structure 300 and the pixel defining layer 330, thereby facilitating preparation of the display panel.

In some embodiments of the present disclosure, in at least two directions parallel to the plane defined by the base plate 100 (e.g., a first direction and a second direction), the ratio of the first distance corresponding to the first-type light-emitting unit 200a to the first distance corresponding to the second-type light-emitting unit 200b ranges from 0.9 to 1.1, that is, the first distance corresponding to the first-type light-emitting unit 200a and the first distance corresponding to the second-type light-emitting unit 200b are substantially equal. Furthermore, in at least two directions parallel to the plane defined by the base plate 100 (e.g., the first direction and the second direction), the first distance corresponding to the first-type light-emitting unit 200a and the first distance corresponding to the second-type light-emitting unit 200b are completely equal. For example, the first direction may be parallel to the X-axis, and the second direction may be parallel to the Y-axis. Along the first direction (the X-axis direction), the first distance (D1-R1) corresponding to the first-type light-emitting unit 200a and the first distance (D1-G1) corresponding to the second-type light-emitting unit 200b are equal. Along the second direction (the Y-axis direction), the first distance (D1-R2) corresponding to the first-type light-emitting unit 200a and the first distance (D1-G2) corresponding to the second-type light-emitting unit 200b are also equal. This facilitates the design of parameters for each light-emitting unit 200 and its adjacent structures, such as the isolation structure 300 and the pixel defining layer 330, thereby facilitating the preparation of the display panel. For example, furthermore, the first distance (D1-R1), the first distance (D1-G1), the first distance (D1-R2), and the first distance (D1-G2) are also equal to each other.

In some embodiments of the present disclosure, in any direction parallel to the plane defined by the base plate 100, the ratio of the first distance corresponding to the first-type light-emitting unit 200a to the first distance corresponding to the second-type light-emitting unit 200b ranges from 0.9 to 1.1, that is, the first distance corresponding to the first-type light-emitting unit 200a and the first distance corresponding to the second-type light-emitting unit 200b are substantially equal. Furthermore, in any direction parallel to the plane defined by the base plate 100, the first distance corresponding to the first-type light-emitting unit 200a and the first distance corresponding to the second-type light-emitting unit 200b are equal. That is, the first distance corresponding to the first-type light-emitting unit 200a at either side is equal to the first distance corresponding to the second-type light-emitting unit 200b at either side.

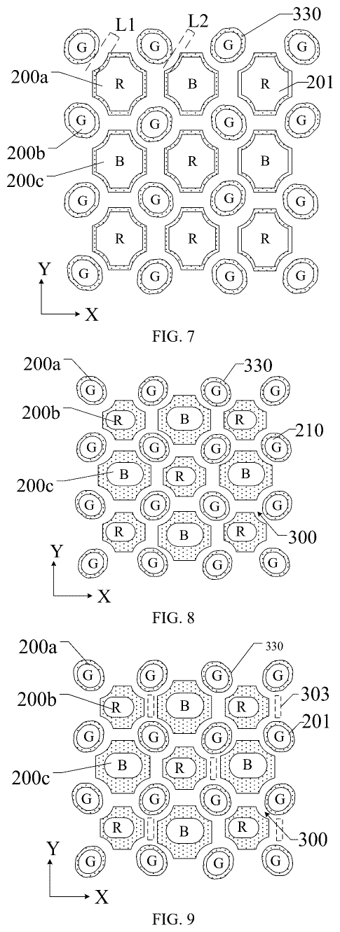

In some embodiments of the present disclosure, as shown in FIG. 7, for the pixel opening 302 and the isolation opening 301 corresponding to the light-emitting unit 200, a distance from the edge of the pixel opening 302 at any position on the base plate 100 to the edge of the isolation opening 301 at the same position on the base plate 100 is constant. That is, within the isolation opening 301, the first ratio at any position along its edge is a constant value. For example, the orthographic projection of the pixel opening 302 on the base plate 100 and the orthographic projection of the isolation opening 301 on the base plate 100 are conformal, with their centers of gravity coinciding. For example, this conformity can be understood as identical shapes but differing in size.

For example, as shown in FIG. 7, an absolute value of a difference between a distance between two adjacent isolation openings 301 and a distance between another two adjacent isolation openings 301 is less than or equal to 2 μm. The absolute value of the distance difference may be 0.1 μm, 0.5 μm, 0.8 μm, 1 μm, 1.3 μm, 1.5 μm, 1.7 μm, or 2 μm. Furthermore, the absolute value of the distance difference is less than or equal to 1 μm. For example, a distance between the isolation opening 301 corresponding to the first-type light-emitting unit 200a and the isolation opening 301 corresponding to the second-type light-emitting unit 200b adjacent thereto is L1; while a distance between the isolation opening 301 corresponding to the second-type light-emitting unit 200b and the isolation opening 301 corresponding to the third-type light-emitting unit 200c adjacent thereto is L2. The absolute value of the difference between L1 and L2 is less than or equal to 2 μm. For example, a width of an interval between adjacent isolation openings 301 may be set to be substantially equal. Thus, the area of the light-emitting region 201 within the light-emitting unit 200 in the display panel may be increased, thereby increasing the aperture ratio of the display panel and improving its display performance.

A width of the isolation structure 300 between two adjacent isolation openings 301 is substantially equal to a width of the isolation structure 300 between another pair of adjacent isolation openings 301. The width of the isolation structure 300 can be understood as: the shortest distance of the isolation structure 300 between two adjacent isolation openings 301, measured along a direction from one isolation opening 301 to the other.

For example, the first distance ranges from 0.5 to 5 μm to enable the display panel to achieve a high aperture ratio. A specific numerical range of the first distance may also be designed based on requirements of an actual process and is not limited to the aforementioned range.

In at least one embodiment of the present disclosure, as shown in FIG. 8, the distance between an orthographic projection of an edge, at a first side, of the pixel opening 302 of at least one light-emitting unit 200 on the base plate 100 (hereinafter referred to as an offset light-emitting unit mentioned in the following) and an orthographic projection of an edge, at the first side, of the isolation opening 301 on the base plate 100 is less than a distance between an orthographic projection of an edge, at a second side, of the pixel opening 302 of the light-emitting unit 200 on the base plate 100 and an orthographic projection of an edge, at the second side, of the isolation opening 301 on the base plate 100. The first side and the second side are opposite sides of the light-emitting unit 200, or the first side and the second side are adjacent sides of the light-emitting unit 200.

At least one of the plurality of light-emitting units 200 (e.g., the light-emitting unit represented by R) is an offset light-emitting unit. The distance between the orthographic projection of the edge, at the first side of the offset light-emitting unit (e.g., a left side of the R light-emitting unit in FIG. 8), of the pixel opening 302 on the base plate 100 and the orthographic projection of the edge, at the first side, of the isolation opening 301 on the base plate 100 is less than the distance between the orthographic projection of the edge, at the second side of the offset light-emitting unit (e.g., a right side of the R light-emitting unit in FIG. 8), of the pixel opening 302 on the base plate 100 and the orthographic projection of the edge, at the second side, of the isolation opening 301 on the base plate 100. The first side and the second side are opposite sides of the offset light-emitting unit.

For example, as shown in FIG. 8, the offset light-emitting unit is the second-type light-emitting unit 200b. The second-type light-emitting unit 200b is surrounded by the first-type light-emitting unit 200a, and the pixel opening 302 (or light-emitting region 201) corresponding to the second-type light-emitting unit 200b has an area that is neither the smallest nor the largest. Therefore, in the arrayed arrangement of the plurality of light-emitting units 200, after positions of the third-type light-emitting unit 200c with the largest area and the first-type light-emitting unit 200a with the smallest area are determined, space may be provided for the offset of the second-type light-emitting unit 200c as the first-type light-emitting units 200a surrounding the second-type light-emitting unit 200b have the smallest area, thereby ensuring that the design area of the second-type light-emitting unit 200 does not affect the area occupied by the entire pixel (including the first-type light-emitting unit 200a, the second-type light-emitting unit 200b, and the third-type light-emitting unit 200c). Areas of the pixel openings 302 (i.e., the area of the light-emitting region 201) corresponding to the first-type light-emitting unit 200a, the second-type light-emitting unit 200a, and the third-type light-emitting unit 200c increase sequentially. The first-type light-emitting unit 200a, the second-type light-emitting unit 200a, and the third-type light-emitting unit 200a emit green light, red light, and blue light, respectively.

In at least one embodiment of the present disclosure, as shown in FIG. 9, a light-transmitting opening 303 may be provided near the offset light-emitting unit to enable functions such as under-display camera operation and fingerprint recognition. The pixel opening 302 of the offset light-emitting unit is offset relative to the isolation opening, allowing the first electrode of the light-emitting unit to be offset with the offset of the pixel opening 302, which ensures sufficient space to be reserved for an arrangement for the light-transmitting opening 303, facilitating the arrangement of the light-transmitting opening 303 around the perimeter of the offset light-emitting unit. For example, at least one light-transmitting opening 303 may be defined by the isolation structure. A distance from the light-transmitting opening 303 to the edge, at the second side (right side), of the offset light-emitting unit is less than a distance from the light-transmitting opening 303 to the edge, at the first side (left side), of the offset light-emitting unit 200. That is, the light-transmitting opening 303 is positioned on a side opposite to the offset direction of the light-emitting unit.

In at least one embodiment of the present disclosure, a width of an orthographic projection of a portion of the isolation structure 300 located between different adjacent isolation openings 301 and/or a portion of the isolation structure 300 located between adjacent isolation opening 301 and light-transmitting opening 303 on the base plate 100 is substantially equal. (A ratio between widths of orthographic projections of the portions of the isolation structure 300 located between different adjacent isolation openings 301 and/or between adjacent isolation opening 301 and light-transmitting opening 303 on the base plate 100, ranges from 0.9 to 1.1), i.e., a width of an internal between adjacent isolation openings 301 and a width of an internal between adjacent isolation opening 301 and light-transmitting opening 303 are both equal. This enables the display panel to achieve both high light transmittance and high pixel arrangement density.

In other embodiments of the present disclosure, the distance between the orthographic projection of the edge of the pixel opening 302 corresponding to the light-emitting unit 200 on the base plate 100 and the orthographic projection of the edge of the corresponding isolation opening 301 on the base plate 100 is referred to as a first distance. The first distance corresponding to the first-type light-emitting unit 200 is less than the first distance corresponding to the second-type light-emitting unit 200. That is, the first distance corresponding to a light-emitting unit 200 with a pixel opening 302 of smaller area is smaller, thereby improving a proportion of light-emitting units 200 with smaller light-emitting areas 201, and further improving the aperture ratio of the display panel. For example, the structure shown in FIG. 6 may be modified such that the first distance (D1-R1) corresponding to the first-type light-emitting unit 200a is less than the first distance (D1-G1) corresponding to the second-type light-emitting unit 200b.

In other embodiments of the present disclosure, the structures shown in FIGS. 3 and 4 may be modified. In a modified structure, the distance D1 between the orthographic projection of the edge of the pixel opening 302 of the light-emitting unit 200 on the base plate 100 and the orthographic projection of the corresponding edge of the isolation opening 301 on the base plate 100 is referred to as the first distance. The first distance corresponding to an emitting unit 200 with a larger pixel opening 302 is less than the first distance corresponding to an emitting unit 200 with a smaller pixel opening 302. For example, the first distance corresponding to the third-type light-emitting unit 200c is less than the first distance corresponding to the second-type light-emitting unit 200b, and the first distance corresponding to the second-type light-emitting unit 200b is less than the first distance corresponding to the first-type light-emitting unit 200a. Thus, the disparity between the first ratio corresponding to the light-emitting unit 200 of a larger area and that corresponding to the light-emitting unit 200 of a smaller area can be further increased, thereby further increasing the proportion of the light-emitting units 200 of the larger area, improving the aperture ratio of the display panel, and reducing the impedance between the light-emitting unit 200 and the isolation structure 300.

In at least one embodiment of the present disclosure, referring again to FIG. 1, the display panel 10 includes a display region 11 and a non-display region 12. Within the display region 11, a sum of the areas of orthographic projections of the isolated openings 301 on the base plate is greater than an area of an orthographic projection of the isolation structure 300 on the base plate. That is, across the entire display region 11 of the display panel 10, the area occupied by the isolated opening 301 need to be greater than the area occupied by the isolation structure 300, thereby reserving sufficient space for arranging the light-emitting units 200, and ensuring an aperture ratio and light extraction efficiency of the display panel 10.

In one example, taking the display region 11 only used for displaying as an example, the display region 11 refers to a region defined by the edges of the isolation openings 201 corresponding to the outermost light-emitting units 200. An area occupied by the isolation structure 300 may be obtained by subtracting a total area of all isolation openings 301 from an area of the display region 11. The area of the display region 11 is related to dimensions of a product and is a preset value that can be directly obtained. The dimensions of the isolation opening 301 are related to a light-emitting area of the light-emitting unit 200 (an area of the light-emitting region, or referred to as an area of the pixel opening). The light-emitting area of the light-emitting unit 200 is also a preset value during product design. Based on the aforementioned first distance, the area of the isolation opening 301 can be directly obtained, thereby allowing the area occupied by the isolation structure 300 to be determined.

In another example, when the display region 11 performs display functions while also incorporating other functions such as light transmission, the light-transmitting opening as mentioned in the aforementioned embodiments may be provided within the display region 11. In this case, the area occupied by the isolation structure 300 may be obtained based on the area of the display region 11, the light-emitting area of the light-emitting unit 200, the first distance, and an area of the light-transmitting opening.

In at least one embodiment of the present disclosure, within a region where the pixel units are located, a ratio of a sum of areas of the orthographic projections of all isolation openings 301 on the base plate to an area of an orthographic projection of the isolation structure 300 on the base plate ranges from 0.1 to 10 to ensure the display panel possesses a high pixel arrangement density and high aperture ratio. Within this numerical range, at least the following pixel arrangements may be adopted to further enhance the pixel arrangement density and the aperture ratio of the display panel. For example, the ratio may be 0.1, 0.5, 1, 2, 3, 4, 5, 6, 7, 8, 9, or 10.

For example, within the region where the pixel units are located, the ratio of the sum of areas of the orthographic projections of all isolation openings 301 on the base plate to the area of the orthographic projection of the isolation structure 300 on the base plate ranges from 0.5 to 5. Specifically, the ratios may be 0.5, 1, 1.5, 2, 2.5, 3, 3.5, 4, or 4.5.

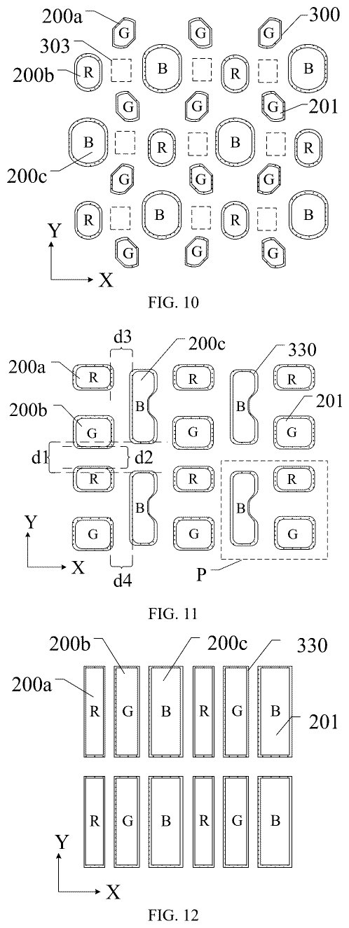

In some examples, as shown in FIG. 10, the light-emitting units 200 of the display panel are classified into a first-type light-emitting unit 200a, a second-type light-emitting unit 200b, and a third-type light-emitting unit 200c with different light-emitting colors. Areas of orthographic projections of the pixel openings 302 corresponding to the first-type light-emitting units 200a, the second-type light-emitting units 200b, and the third-type light-emitting units 200c increase in sequence. Wavelengths of light emitted by the second-type light-emitting unit 200b (e.g., R), the first-type light-emitting unit 200a (e.g., G), and the third-type light-emitting unit 200c (e.g., B) decrease successively. In a row direction (e.g., X-axis direction) and a column direction (e.g., Y-axis direction), the second-type light-emitting unit 200b and the third-type light-emitting unit 200c are alternately arranged. Rows including the second-type light-emitting unit 200b and the third-type light-emitting unit 200c are alternately arranged with rows including the first-type light-emitting unit 200a. Columns including the second-type light-emitting unit 200b and the third-type light-emitting unit 200c are alternately arranged with columns including the first-type light-emitting unit 200a. A distance between an orthographic projection of an edge of the pixel opening corresponding to the light-emitting unit 200 on the base plate and an orthographic projection of an edge of the corresponding isolation opening on the base plate is referred to as a first distance. The first distance corresponding to the first-type light-emitting unit 200a, the first distance corresponding to the second-type light-emitting unit 200b, and the first distance corresponding to the third-type light-emitting unit 200c are all equal. The first ratio corresponding to the first-type light-emitting unit 200a is less than the first ratio corresponding to the second-type light-emitting unit 200b, and also smaller than the first ratio corresponding to the third-type light-emitting unit 200c.

For example, as shown in FIG. 10, both the second-type light-emitting unit 200b and the third-type light-emitting unit 200c are configured as a shape like a racetrack. The shape like the racetrack includes two opposing curved sides and two opposing straight sides. In both the second-type light-emitting unit 200b and the third-type light-emitting unit 200c, the straight sides extend in the column direction. The first-type light-emitting unit 200a includes two opposing oblique sides, two opposing straight sides, and two opposing smooth sides. In the first-type light-emitting unit 200a, the oblique sides intersect both the row and column directions, and the straight sides extend along the column direction. One end of each straight side connects to an oblique side to form an obtuse angle, while the other end connects to another oblique side via a smooth side. The smooth sides smoothly interface with both an adjacent oblique side and an adjacent straight side.

In the pixel arrangement shown in FIG. 10, widths of the isolation structure at intervals between isolation openings 301 are not uniform. Thus, a position where the isolation structure has a larger width may be provided with a light-transmitting opening 303.

In other examples, as shown in FIG. 11, the light-emitting units 200 of the display panel are classified into a first-type light-emitting units 200a, a second-type light-emitting units 200b, and a third-type light-emitting units 200c with different light-emitting colors. Areas of orthographic projections of the pixel openings 302 corresponding to the first-type light-emitting unit 200a, the second-type light-emitting unit 200b, and the third-type light-emitting unit 200c sequentially increase. Wavelengths of light emitted by the second-type light-emitting unit 200b (e.g., R), the first-type light-emitting unit 200a (e.g., G), and the third-type light-emitting unit 200c (e.g., B) decrease successively. A plurality of light-emitting units are arranged in rows (along the X-axis direction) and columns (along the Y-axis direction). At least one pixel unit P includes the first-type light-emitting unit 200a, the second-type light-emitting unit 200b, and the third-type light-emitting unit 200c. Within a pixel unit P, the first-type light-emitting unit 200a and the second-type light-emitting unit 200b are arranged in the same column. Both the first type light-emitting unit 200a and the second type light-emitting unit 200b are arranged in the same row as the third type light-emitting unit 200c. Within a column including the first type light-emitting unit 200a, the first type light-emitting unit 200a and the second type light-emitting unit 200b arranged alternately. The column including the first-type light-emitting unit 200a and the second-type light-emitting unit 200b and the columns including the third-type light-emitting unit 200c are alternately arranged in the row direction (e.g., the direction of the X-axis).

For example, a distance between an orthographic projection of an edge of the pixel opening 302 corresponding to the light-emitting unit 200 on the base plate and an orthographic projection of an edge of the corresponding isolation opening 301 on the base plate is referred to as a first distance. The first distance corresponding to the first-type light-emitting unit 200a, the first distance corresponding to the second-type light-emitting unit 200b, and the first distance corresponding to the third-type light-emitting unit 200c are all equal. The first ratio corresponding to the first-type light-emitting unit 200a is less than the first ratio corresponding to the second-type light-emitting unit 200b, and also less than the first ratio corresponding to the third-type light-emitting unit 200c.

In the column direction, a distance d1 between a third-type light-emitting unit 200c in a pixel unit P and a third-type light-emitting unit 200c in an adjacent pixel unit P is greater than the minimum distance d2 between a first-type light-emitting unit 200a in one pixel unit P and a second-type light-emitting unit 200b in an adjacent pixel unit P. A distance d3 between a first-type light-emitting unit 200a and a third-type light-emitting unit 200c in the same row but adjacent column is less than the distance d1 between two adjacent third-type light-emitting units 200c in the same column. A distance d4 between a second type light-emitting unit 200b and a third type light-emitting unit 200c in the same row and adjacent column is less than the distance d1 between two adjacent third type light-emitting units 200c in the same column.

For example, as shown in FIG. 11, the first-type light-emitting units 200a and second-type light-emitting unit 200b are rectangular in shape with their length directions parallel to the row direction. The third-type light-emitting units 200c include two opposite short sides, a long side, and an irregular side. Within the third-type light-emitting unit 200c, the two short sides are opposite each other and extend along the row direction. The two short sides of the third type light-emitting unit 200c are parallel to the long sides of the first type light-emitting unit 200a and the second type light-emitting unit 200b. The long side and the irregular side of the third type light-emitting unit 200c are opposite each other. The long side extends along the column direction, and at least part of the irregular side is recessed toward a center of gravity of the third type light-emitting unit 200c. For example, a side of the third type light-emitting unit 200c with the recess can be used to provide a light-transmitting opening.

In other examples, as shown in FIG. 12, the light-emitting unit 200 of the display panel includes a first-type light-emitting unit 200a, a second-type light-emitting unit 200b, and a third-type light-emitting unit 200c emitting light of different colors. Areas of orthographic projections of the pixel openings 302 corresponding to the first-type light-emitting unit 200a, the second-type light-emitting unit 200b, and the third-type light-emitting unit 200c sequentially increase. Wavelengths of light emitted by the second-type light-emitting unit 200b (e.g., R), the first-type light-emitting unit 200a (e.g., G), and the third-type light-emitting unit 200c (e.g., B) decrease successively. A plurality of light-emitting units are arranged in rows (along the X-axis direction) and columns (along the Y-axis direction). The first-type light-emitting unit 200a, the second-type light-emitting unit 200b, and the third-type light-emitting unit 200c are arranged in separate columns, i.e., they are arranged in different columns. Columns including the first-type light-emitting unit 200a, the second-type light-emitting unit 200b, and the third-type light-emitting unit 200c are arranged in sequence and alternately. Sequential arrangement can be understood as the columns including the first-type light-emitting unit 200a, the second-type light-emitting unit 200b, and the third-type light-emitting unit 200c repeating periodically. Within each cycle, the columns including the first-type light-emitting unit 200a, the second-type light-emitting unit 200b, and the third-type light-emitting unit 200c are arranged in sequence. A distance between an orthographic projection of an edge of the pixel opening corresponding to the light-emitting unit 200 on the base plate and an orthographic projection of an edge of the corresponding isolation opening on the base plate is referred to as a first distance. The first distance corresponding to the first-type light-emitting unit 200a, the first distance corresponding to the second-type light-emitting unit 200b, and the first distance corresponding to the third-type light-emitting unit 200c are all equal. The first ratio corresponding to the first-type light-emitting unit 200a is less than the first ratio corresponding to the second-type light-emitting unit 200b, and also smaller than the first ratio corresponding to the third-type light-emitting unit 200c.

For example, as shown in FIG. 12, the first-type light-emitting unit 200a, the second-type light-emitting unit 200b, and the third-type light-emitting unit 200cB are elongated units whose extension direction is parallel to the column direction. Within each row, ends of the first-type light-emitting unit 200a, the second-type light-emitting unit 200b, and the third-type light-emitting unit 200c at the same side may define a straight line, and an extension direction of the straight line is parallel to the row direction.

In the embodiments of the present disclosure, specific structural design of the isolation structure, the light-emitting units, etc., is not limited and may be designed based on the requirements of the actual process. Below, configuration methods of these structures will be exemplary illustrated through several specific embodiments.

In at least one embodiment of the present disclosure, with reference again to FIG. 4, the isolation structure 300 may include a support portion 310 facing the base plate 100 and a crown portion 320 facing away from the base plate 100. An orthographic projection of the support portion 310 on the base plate 100 is located within an orthographic projection of the crown portion 320 on the base plate 100. That is, the isolation structure 300 generally appears to be wider at the top and narrower at the bottom. This configuration allows certain film layers to be disconnected at the edge of the isolation structure 300 during vapor-deposition of the light-emitting unit 200 (e.g., the light-emitting function layer 30 described below), thereby reducing the risk of crosstalk between adjacent light-emitting units.

In at least one embodiment of the present disclosure, referring again to FIG. 4, the light-emitting unit 200 includes a first electrode 210, a light-emitting function layer 220, and a second electrode 230 sequentially stacked on the base plate 100. The light-emitting function layer 220 and the second electrode 230 of the light-emitting unit 200 are located within the corresponding isolation opening 301. During the preparation of the light-emitting function layer 220, the isolation structure 300 (crown portion 320) may limit a diffusion range of the evaporated material. Consequently, an orthogonal projection of an edge of the crown portion 320 on the base plate 100 is located within the orthogonal projections of the light-emitting function layer 220 and the second electrode 230 on the base plate 100. A manufacturing method for a display panel in the following embodiments may be referred to for relevant descriptions, which will not be repeated herein.

For example, the light-emitting function layer may further include a first functional layer 221, a light-emitting layer 222, and a second functional layer 223, sequentially stacked on the first electrode 210. The first functional layer 221 may include a hole injection layer, a hole transport layer, and an electron blocking layer. The second functional layer 223 may include an electron injection layer, an electron transport layer, and a hole blocking layer. Since charge carriers (holes, electrons) primarily crosstalk between adjacent light-emitting units 200 through the first functional layer 221, the isolation structure 300 needs to be arranged so as to ensure that the first functional layer 221 of each light-emitting unit 200 is electrically isolated from each other.

For example, in at least one embodiment of the present disclosure, the first electrode 210 may be configured as an anode, and the second electrode 230 may be configured as a cathode.

Since the isolation structure 300 has a shape that is wider at the top and narrower at the bottom, the first functional layer 221 will be disconnected at the edge of the crown portion 320 during the evaporation process. That is, the first functional layer 221 will not connect to a conductive portion of the isolation structure 300 (e.g., the support portion 310), thereby preventing crosstalk between adjacent light-emitting units 200.

In the embodiments of the present disclosure, the isolation structure is used to connect the second electrode. To prevent the isolation structure from connecting to the first electrode, dimensions of the first electrode may be reduced to create a gap with the isolation structure, or an insulating layer may be provided between the first electrode and the isolation structure.

In at least one embodiment of the present disclosure, the pixel defining layer 330 may be an inorganic film layer. The inorganic layer exhibits high density and strong resistance capability, thereby enabling a reduction in a design thickness of the display panel. Furthermore, a thinner pixel defining layer 330 facilitates the continuity of the second electrode 230.

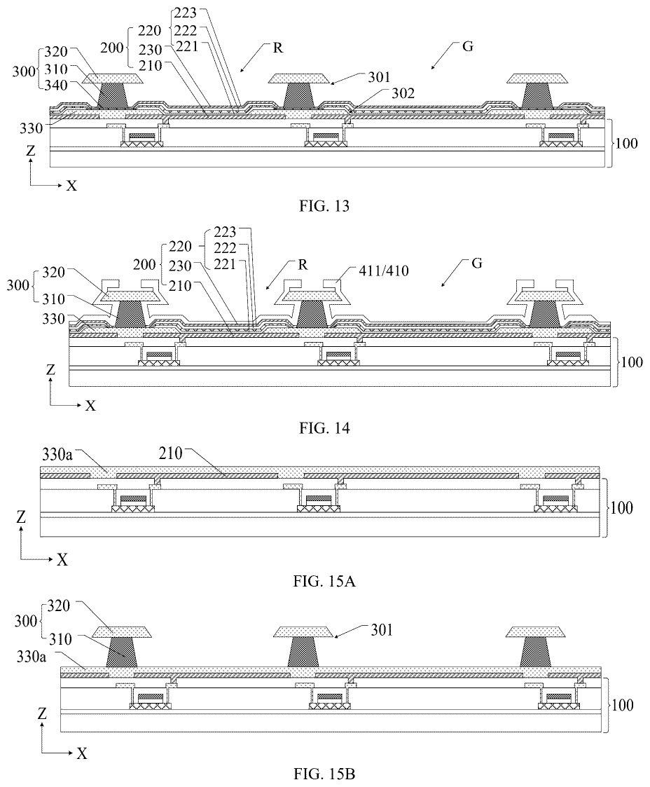

In at least one embodiment of the present disclosure, as shown in FIG. 13, the isolation structure 300 may further include an auxiliary support portion 340. The auxiliary support portion 340 is located on a side, facing away from the crown portion 320, of the support portion 310, and an orthographic projection of the auxiliary support portion 340 on the base plate 100 is located within the orthographic projection of the crown portion 320 on the base plate 100, and the orthographic projection of the support portion 310 on the base plate 100 is located within the orthographic projection of the auxiliary support portion 340 on the base plate 100.

For example, the auxiliary support portion 340 may be a conductive structure. The portion of a surface, facing away from the base plate 100, of the auxiliary support portion 340 that is not covered by the support portion 310 may be used to contact the second electrode 230. Relative to the side wall of the support portion 310, a deposition thickness of the second electrode 230 on the surface of the auxiliary support portion 340 is greater. Thus, the auxiliary support portion 340 has a larger contact area and bonding strength with the second electrode 230, thereby reducing the impedance between the second electrode 230 and the isolation structure 300.

For example, the crown portion 320, the support portion 310, and the auxiliary support portion 340 may be sequentially made of titanium, aluminum, and molybdenum, respectively. Corrosion resistance of titanium, molybdenum, and aluminum decreases in that order, thereby enabling the formation of the isolation structure 300 as shown in FIG. 13.

In the embodiments of the present disclosure, the second electrode 230 need only be connected to the isolation structure 300. When the auxiliary support portion 340 is provided, the second electrode 230 may be connected only to the auxiliary support portion 340, or alternatively, the second electrode 230 may be connected to both the auxiliary support portion 340 and the support portion 310.

For example, in some embodiments of the present disclosure, the support portion 310 and the crown portion 320 may form an integrated structure, the auxiliary support portion 340 may be a conductive structure, and the second electrode 230 of the light-emitting unit 200 may be connected to the auxiliary support portion 340. Furthermore, along a direction perpendicular to the base plate 100, a cross-sectional shape of the crown portion 320 is an inverted trapezoid, with the top edge of the inverted trapezoid facing the base plate 100, i.e., the top edge of the inverted trapezoid is located between the base plate 100 and the bottom edge of the inverted trapezoid.

For example, in other embodiments of the present disclosure, the support portion 310 and the crown portion 320 are two separate film layers, and the auxiliary support portion 340 is a conductive structure. The second electrode 230 of the light-emitting unit 200 is connected to the auxiliary support portion 340. For example, along a direction perpendicular to the base plate 100, the cross-sectional shape of the auxiliary support portion 340 is a right trapezoid. In this configuration, it facilitates the deposition of vapor deposition of material of the second electrode 230 onto sidewalls of the auxiliary support portion 340, thereby enhancing a connection yield between the second electrode 230 and the auxiliary support portion 340, and reducing the impedance at a connection point between the second electrode 230 and the isolation structure 300. Under this design, the support portion 310 and the crown portion 320 may be made of different materials, such as the aforementioned titanium, aluminum, molybdenum, etc. Alternatively, when the auxiliary support portion 340 is configured as a conductive structure, the crown portion 320 and the support portion 310 may be configured as non-conductive structures, such as inorganic layers, to enhance bonding strength with subsequent encapsulation structures (e.g., a first encapsulation layer described below).

In at least one embodiment of the present disclosure, as shown in FIG. 14, the display panel may further include a first encapsulation layer 410. The first encapsulation layer 410 includes a plurality of encapsulation units 411 corresponding to a plurality of isolation opening 301 in one-to-one correspondence, where the encapsulation unit 411 covers the corresponding isolation opening 301.

In at least one embodiment of the present disclosure, as shown in FIG. 14, at least for the purpose of improving the encapsulation effect, the encapsulation unit 411 may extend to the side, faces away from the base plate 100, of the crown portion 320 and may be spaced apart from a surface, facing away from the base plate 100, of the crown portion 320. The principle may be understood by referring to relevant description in the embodiments shown in FIGS. 15A to 15F below. In this case, a cantilevered section spaced apart from the crown portion 320 may be formed at a position where the crown portion 320, overlaps with the encapsulation unit 411.

In the embodiments disclosed herein, when the light-emitting unit 200 includes a plurality of types of light-emitting units 200 emitting light of different colors, the light-emitting units 200 emitting different light are independently fabricated. However, the film layers (such as vapor-deposited layers including the light-emitting function layer) within the light-emitting unit 200 are deposited across the entire display panel surface during the vapor deposition process. For example, when light-emitting units 200 are classified into light-emitting units emitting red light (R), green light (G), and blue light (B), respectively, the light-emitting units R, G, and B are fabricated sequentially during the preparation process. During the fabrication of the light-emitting unit R, a light-emitting unit R is formed within each isolation opening 301. A first encapsulation layer 410 is then applied over the display panel to cover the light-emitting unit R. Then, the first encapsulation layer 410 (excluding isolation openings corresponding to the light-emitting unit R and surrounding isolation structures), along with the second electrode and light-emitting function layer of the red light-emitting unit, are removed to obtain the encapsulated unit 411. Based on this method, the light-emitting unit G and the light-emitting unit B are sequentially prepared, ultimately forming the first encapsulation layer 410 as shown in FIG. 14. That is, the entire first encapsulation layer 410 across the display panel is obtained through multiple sequential processes.

Based on the above method for preparing the light-emitting unit 200, the encapsulation units 411 corresponding to the light-emitting units 200 emitting light of different colors are also formed in different steps. Therefore, encapsulation units 411 corresponding to adjacent light-emitting units emitting light of different colors are either spaced apart or overlapped with each other. Correspondingly, the encapsulation units 411 corresponding to light-emitting units 200 emitting light of the same color are also formed in the same step. Therefore, the encapsulation units 411 corresponding to adjacent light-emitting units 200 emitting light of the same color may be configured to be connected to each other or spaced apart from each other.

In the embodiments of the present disclosure, the preparation sequence for the three types of light-emitting units R, G, and B is not restricted and can be designed according to the requirements of the actual process. For example, the preparation process may also be implemented based on the sequence of light-emitting units B, G, and R.

In the following, the preparation process of the display panel shown in FIG. 14 will be described with reference to FIGS. 15A to 15F to visually demonstrate how the isolation structure can increase the PPI.

As shown in FIG. 15A, a base plate 100 is provided, and a first electrode 210 is formed in an array configuration on the base plate 100. An insulating material film layer 330a (e.g., an inorganic material film layer) is deposited on the base plate 100 with the formed first electrode 210.

As shown in FIG. 15B, an isolation structure 300 including a support portion 310 and a crown portion 320 is formed on the display panel.

As shown in FIG. 15C, a patterning process is performed on the insulating material film layer 330a to form a pixel defining layer 330 (with a planar shape resembling a grid). The pixel defining layer 330 covers intervals between adjacent first electrodes 210, thereby exhibiting a planar grid-like configuration.

In the embodiments of the present disclosure, the patterning process may be a photolithographic patterning process, which may include: coating a photoresist on a structural layer to be patterned; exposing the photoresist using a mask; developing the exposed photoresist to obtain a photoresist pattern; etching the structural layer using the photoresist pattern (in one embodiment, wet etching or dry etching); and then, in one embodiment, removing the photoresist pattern. When the material of the structural layer (e.g., the photoresist pattern 500 described below) includes photoresist, the structural layer may be directly exposed through a mask to form the desired pattern.

As shown in FIG. 15D, a light-emitting function layer 220 and a second electrode 230 are deposited on the base plate 100 to form a light-emitting unit 200 within each isolation opening 301 of the isolation structure 300. This deposition process does not employ a mask, allowing the deposited material to also coat the crown region 320. Subsequently, a first encapsulation film layer 410a is deposited to cover the light-emitting units 200. For example, the light-emitting layer in the evaporated light-emitting function layer 220 may be used to emit red light. Thus, at this stage, a light-emitting unit 200 emitting red light (R) may be formed in each isolation opening 301 in the isolation structure 300.

As shown in FIG. 15E, photoresist is formed (e.g., coated) on the base plate 100 bearing the first encapsulation layer 410a. A patterning process is then performed to create photoresist pattern 500, which covers only part of the isolation structure 300 and the isolation openings 301.

As shown in FIG. 15F, the surface of the display panel is etched using the photoresist pattern 500 as a mask, to remove the first encapsulation film layer 410a, the second electrode 230, and the light-emitting function layer 220 not covered by the photoresist pattern 500. The remaining portion of the first encapsulation film layer 410a forms the encapsulation unit 411 as shown in FIG. 14. Then, the residual photoresist pattern 500 is removed.

Steps shown in FIGS. 15A to 15F are repeated to form the light-emitting units 200 emitting green light and the light-emitting units 200 emitting blue light in the other isolation openings 301, respectively, thereby forming the display panel shown in FIG. 14.

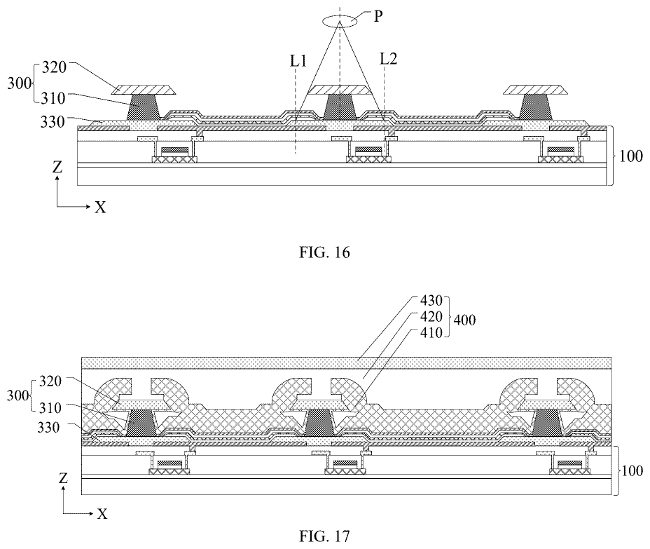

As shown in FIG. 16, when depositing the light-emitting function layer (e.g., the first functional layer), if the deposition source P moves to align directly opposite the isolation structure 300, a boundary of the deposition corresponds to lines L1 and L2 on the display panel. That is, an area between lines L1 and L2 will not be deposited in this case, while an area on sides, away from the isolation structure 300, of lines L1 and L2 will be deposited regardless of the position of the deposition source P. That is, starting from a region of line L1 or line L2, the closer to the isolation structure 300, the smaller the thickness of the light-emitting function layer.

In at least one embodiment of the present disclosure, as shown in FIG. 17, a space may be formed on a side of the isolation structure 300 by the first encapsulation layer 410. Furthermore, a portion, covering the crown section 320, of the first encapsulation layer 410 closes (contacts) with a portion, covering the light-emitting unit 200, of the first encapsulation layer 410, thereby sealing the space. This prevents harmful materials such as etching solutions or gases from entering the sealed space during the fabrication process of different types of light-emitting units.

In at least one embodiment of the present disclosure, as shown in FIG. 17, the display panel may further include a second encapsulation layer 420 and a third encapsulation layer 430 covering the first encapsulation layer 410 and the isolation structure 300. The second encapsulation layer 420 is located between the first encapsulation layer 410 and the third encapsulation layer 430. The first encapsulation layer 410, the second encapsulation layer 420, and the third encapsulation layer 430 collectively form the encapsulation structure 400.

In at least one embodiment of the present disclosure, as shown in FIG. 17, the first encapsulation layer 410 and the third encapsulation layer 430 are inorganic layers, while the second encapsulation layer 420 is an organic layer. For example, the second encapsulation layer 420 further provides a planarizing function. The inorganic layers exhibit high density to block water vapor and oxygen, while the second encapsulation layer 420, being organic, possesses greater thickness to flatten the surface of the display panel.

In at least one embodiment of the present disclosure, as shown in FIG. 17, the base plate 100 may include a substrate and a drive circuit layer disposed on the substrate. The drive circuit layer includes a plurality of pixel drive circuits located within the display region, with the display function layer positioned on top of the drive circuit layer. For example, the pixel drive circuit may include a plurality of transistors (TFTs), capacitors, etc., configured in various forms such as 2T1C (i.e., 2 transistors (TFTs) and 1 capacitor (C)), 3T1C, or 7T1C. The pixel drive circuit is connected to the light-emitting unit 200 to control a switching state and luminance of the light-emitting unit 200. An orthographic projection of the pixel drive circuit on the base plate overlaps with an orthographic projection of the isolation structure on the base plate and an orthographic projection of the first electrode on the base plate.

At least one embodiment of the present disclosure provides a display panel including a base plate, an isolation structure disposed on the base plate, a pixel-defining layer, and a plurality of light-emitting units. The pixel defining layer is located on a side of the base plate and a plurality of pixel openings are defined by the pixel defining layer. The isolation structure is located on a side, facing away from the base plate, of the pixel defining layer and a plurality of isolation openings are defined by the isolation structure. The plurality of isolation openings are respectively in communication with corresponding pixel openings. At least part of the light-emitting unit is located in the isolation openings and the light-emitting units include a first-color light-emitting unit and a second-color light-emitting unit. An area of the pixel opening corresponding to the first-color light-emitting unit is smaller than an area of the pixel opening corresponding to the second-color light-emitting unit. A ratio of an area of an orthographic projection of the pixel opening corresponding to the first-color light-emitting unit on the base plate to an area of an orthographic projection of the corresponding isolation opening on the base plate is less than a ratio of an area of an orthographic projection of the pixel opening corresponding to the second-color light-emitting unit on the base plate to an area of an orthographic projection of the corresponding isolation opening on the base plate. In this display panel, by setting different first ratios between different light-emitting units, a proportion of the light-emitting area may be adjusted based on types of the light-emitting unit. This balances the light-emitting efficiency of the light-emitting units of different colors, thereby regulating the display effect of the display panel. Additionally, this scheme can adjust a contact area between different types of light-emitting units and the isolation structure, thereby regulating the impedance between different types of light-emitting units and the isolation structure. This addresses the issue of uneven voltage drop distribution during operation, thereby enhancing the display performance of the display panel. The first-color light-emitting unit and the second-color light-emitting unit emit light of different colors. The first-color light-emitting unit and the second-color light-emitting unit may respectively refer to the first-type light-emitting unit and the second-type light-emitting unit described in the aforementioned embodiments, and are not described in detail herein. Furthermore, the structure of the display panel and its further design may refer to the relevant descriptions in the aforementioned embodiments and are not described in detail herein.

In at least one embodiment of the present disclosure, the plurality of light-emitting units may further include a third-color light-emitting unit. The area of the second-color light-emitting unit is smaller than an area of the third-color light-emitting unit. The ratio of the orthographic projection area of the pixel opening corresponding to the second-color light-emitting unit on the base plate to the orthographic projection area of the corresponding isolation opening on the base plate is less than a ratio of an area of an orthographic projection of the pixel opening corresponding to the third color light-emitting unit on the base plate to an area of an orthographic projection of the corresponding isolation opening on the base plate. The colors of light emitted by the first-color light-emitting unit, the second-color light-emitting unit, and the third-color light-emitting unit are all different. The third-color light-emitting unit may refer to the third-type light-emitting unit in the aforementioned embodiments and is not described in detail herein. The structure of the display panel, the problems solved, the corresponding effects, and further design possibilities may refer to the relevant descriptions in the aforementioned embodiments and are not described in detail herein.

At least one embodiment of the present disclosure provides a display panel including a base plate, an isolation structure disposed on the base plate, a pixel defining layer, and a plurality of light-emitting units. The pixel defining layer is located on a side of the base plate and a plurality of pixel openings are defined by the pixel defining layer. The isolation structure is located on a side, facing away from the base plate, of the pixel defining layer and a plurality of isolation openings are defined by the isolation structure. The plurality of isolation openings are respectively in communication with corresponding pixel openings. At least part of the light-emitting unit is located in the isolation openings and the light-emitting units include a first-type light-emitting unit and a second-type light-emitting unit. A perimeter of an orthographic projection of the pixel opening corresponding to the light-emitting unit on the base plate is less than a perimeter of an orthographic projection of the isolation opening corresponding to the light-emitting unit on the base plate, and a ratio of the perimeter of the orthographic projection of the pixel opening corresponding to the light-emitting unit on the base plate to the perimeter of the orthographic projection of the corresponding isolation opening on the base plate is referred to as a second ratio; and the second ratio corresponding to the first-type light-emitting unit is less than the second ratio corresponding to the second-type light-emitting unit. In this display panel, by setting different second ratios between different light-emitting units, the perimeter proportion of their light-emitting regions is adjusted based on the type of light-emitting unit. This balances the light-emitting efficiency of the light-emitting units emitting light of different colors, thereby regulating the display effect of the display panel. Additionally, this scheme can adjust a connection perimeter between different types of light-emitting units and the isolation structure, thereby regulating the impedance between them. This addresses the issue of uneven voltage drop distribution across the display panel during operation, enhancing its display performance. The first-color light-emitting unit and the second-color light-emitting unit emit light of different colors. The first-type light-emitting unit and the second-type light-emitting unit emit light of different colors. The first-type light-emitting unit and the second-type light-emitting unit may respectively refer to the first-color light-emitting unit and the second-color light-emitting unit described in the aforementioned embodiments, and are not described in detail herein. Furthermore, the structure of the display panel and its further design may refer to the relevant descriptions in the aforementioned embodiments and are not described in detail herein.

For example, in at least one embodiment of the present disclosure, a larger perimeter of a pixel opening corresponds to a larger area of the pixel opening.

In at least one embodiment of the present disclosure, the perimeter of the orthographic projection of the pixel opening corresponding to the first-type light-emitting unit on the base plate is less than the perimeter of the orthographic projection of the pixel opening corresponding to the second-type light-emitting unit on the base plate. For example, the area of the orthographic projection of the pixel opening corresponding to the first-type light-emitting unit on the base plate is also smaller than the area of the orthographic projection of the pixel opening corresponding to the second-type light-emitting unit on the base plate. The structure of the display panel, the problems solved, the corresponding effects, and further design possibilities can be found in the relevant descriptions of the aforementioned embodiments and will not be repeated here.

In at least one embodiment of the present disclosure, the plurality of light-emitting units may further include a third-color light-emitting unit. The perimeter of the orthographic projection of the pixel opening corresponding to the second-type light-emitting units on the base plate is less than a perimeter of the orthographic projection of the pixel opening corresponding to the third-color light-emitting units on the base plate. The second ratio corresponding to the second-type light-emitting unit is less than the second ratio corresponding to the third-type light-emitting unit. Colors of light emitted by the first-color light-emitting unit, the second-color light-emitting unit, and the third-color light-emitting unit are all different. The third-color light-emitting unit may refer to the third-type light-emitting unit in the aforementioned embodiments and is not described in detail herein. The structure of the display panel, the problems solved, the corresponding effects, and further design possibilities may refer to the relevant descriptions in the aforementioned embodiments and are not described in detail herein. This application imposes no restrictions on the numerical range of the second ratio, which may be designed according to requirements of an actual process. For example, in at least one embodiment disclosed herein, the second ratio may range from 0.2 to 0.9. The second ratio may be 0.2, 0.3, 0.4, 0.5, 0.6, 0.7, 0.8, or 0.9, among others. The second ratio corresponding to the light-emitting unit (e.g., the third type light-emitting unit 200) corresponding to a pixel opening 302 with the largest perimeter ranges from 0.5 to 0.9.

At least one embodiment of the present disclosure provides a display device. The display device may include the display panel described in the aforementioned embodiments. For example, the display device may include structures such as a touch control structure, optical films (e.g., microlenses, polarizers), and cover plates positioned on a light-emitting side of the display panel.

For example, the display device may be any product or component with display functionality, such as televisions, digital cameras, mobile phones, watches, tablet computers, notebook computers, or navigation devices.

The above description is merely an exemplary embodiment of the present specification and is not intended to limit the scope of the present specification. Any modifications, equivalent replacements, or other adaptations made within the spirit and principles of the present specification shall be included within the scope of protection of the present specification. W hat is claimed is:

1. A display panel, comprising:
a base plate;
a pixel defining layer disposed on a side of the base plate and provided with a plurality of pixel openings;
an isolation structure disposed on a side, facing away from the base plate, of the pixel defining layer, and defining a plurality of isolation openings respectively in communication with the corresponding pixel openings; and
a plurality of light-emitting units comprising at least a first-type light-emitting unit and at least a second-type light-emitting unit, at least part of a light-emitting unit being located in the isolation opening;
wherein a ratio of an area of an orthographic projection of the pixel opening corresponding to the light-emitting unit on the base plate to an area of an orthographic projection of the isolation opening corresponding to the light-emitting unit on the base plate is referred to as a first ratio, and
the first ratio corresponding to the first-type light-emitting unit is less than the first ratio corresponding to the second-type light-emitting unit.

2. The display panel according to claim 1, wherein an area of an orthographic projection of the pixel opening corresponding to the first-type light-emitting unit on the base plate is smaller than an area of an orthographic projection of the pixel opening corresponding to the second-type light-emitting unit on the base plate; and
the orthographic projection of the pixel opening on the base plate is located within the orthographic projection of the corresponding isolation opening on the base plate.

3. The display panel according to claim 2, wherein the plurality of light-emitting units further comprise a third-type light-emitting unit, the area of the orthographic projection of the pixel opening corresponding to the second-type light-emitting unit is smaller than an area of an orthographic projection of the pixel opening corresponding to the third-type light-emitting unit, and the first ratio corresponding to the second-type light-emitting unit is less than the first ratio corresponding to the third-type light-emitting unit.

4. The display panel according to claim 3, wherein wavelengths of light emitted by the first-type light-emitting unit, the second-type light-emitting unit, and the third-type light-emitting unit decrease sequentially; or
the wavelengths of light emitted by the second-type light-emitting unit, the first-type light-emitting unit, and the third-type light-emitting unit decrease sequentially.

5. The display panel according to claim 1, wherein the first ratio ranges from 0.2 to 0.9.

6. The display panel according to claim 1, wherein a distance between an orthographic projection of an edge of the pixel opening corresponding to the light-emitting unit on the base plate and an orthographic projection of an edge of the isolation opening corresponding to the pixel opening on the base plate is referred to as a first distance; and
in a direction parallel to a plane located by the base plate, a ratio of the first distance corresponding to the first-type light-emitting unit to the first distance corresponding to the second-type light-emitting unit ranges from 0.9 to 1.1.

7. The display panel according to claim 1, wherein for the pixel opening and the isolation opening corresponding to the light-emitting unit, a distance from each position of an orthographic projection of an edge of the pixel opening on the base plate to an orthographic projection of an edge of the isolation opening on the base plate is constant.

8. The display panel according to claim 7, wherein a distance between the orthographic projection of the edge of the pixel opening corresponding to the light-emitting unit on the base plate and the orthographic projection of the edge of the isolation opening corresponding to the pixel opening on the base plate is referred to as a first distance, and
the first distance corresponding to the first-type light-emitting unit is less than the first distance corresponding to the second-type light-emitting unit.

9. The display panel according to claim 1, wherein an absolute value of a difference between a distance between two adjacent isolation openings and a distance between another two adjacent isolation openings is less than or equal to 2 μm.

10. The display panel according to claim 1, wherein a distance between an orthographic projection of an edge of the pixel opening at a first side of at least one light-emitting unit on the base plate and an orthographic projection of an edge of the isolation opening corresponding to the pixel opening at the first side of the at least one light-emitting unit on the base plate is less than a distance between an orthographic projection of an edge of the pixel opening at a second side of the at least one light-emitting unit on the base plate and an orthographic projection of an edge of the isolation opening corresponding to the pixel opening at the second side of the at least one light-emitting unit on the base plate; and
the first side and the second side are opposite sides of the light-emitting unit, or the first side and the second side are adjacent sides of the light-emitting unit.

11. The display panel according to claim 2, comprising a display region and a non-display region, wherein,
in the display region, a sum of areas of orthographic projections of the plurality of isolation openings on the base plate is greater than an area of an orthographic projection of the isolation structure on the base plate.

12. The display panel according to claim 2, wherein the at least a first-type light-emitting unit comprises a plurality of first-type light-emitting units, the at least a second-type light-emitting unit comprises a plurality of second-type light-emitting units,
the plurality of light-emitting units further comprise a plurality of third-type light-emitting units, areas of orthographic projections of the pixel openings corresponding to the first-type light-emitting unit, the second-type light-emitting unit, and the third-type light-emitting unit respectively, on the base plate, increase sequentially, and wavelengths of light emitted by the second-type light-emitting unit, the first-type light-emitting unit, and the third-type light-emitting unit decrease sequentially;
in both row and column directions, the second-type light-emitting units and the third-type light-emitting units are alternately arranged, rows comprising the second type and third-type light-emitting units and rows comprising the first-type light-emitting units are alternately arranged, and columns comprising the second type light-emitting units and the third-type light-emitting units and columns comprising the first-type light-emitting units are alternately arranged;
a distance between an orthographic projection of an edge of the pixel opening corresponding to the light-emitting unit on the base plate and an orthographic projection of an edge of the isolation opening corresponding to the pixel opening on the base plate is referred to as a first distance, and the first distance corresponding to the first-type light-emitting unit, the first distance corresponding to the second-type light-emitting unit, and the first distance corresponding to the third-type light-emitting unit are all equal; and
the first ratio corresponding to the first-type light-emitting unit is less than the first ratio corresponding to the second-type light-emitting unit, and less than the first ratio corresponding to the third-type light-emitting unit.

13. The display panel according to claim 3, wherein the at least a first-type light-emitting unit comprises a plurality of first-type light-emitting units, the at least a second-type light-emitting unit comprises a plurality of second-type light-emitting units,
the plurality of light-emitting units further comprise a plurality of third-type light-emitting units, areas of orthographic projections of the pixel openings corresponding to the first-type light-emitting unit, the second-type light-emitting unit, and the third-type light-emitting unit respectively, on the base plate, increase sequentially, and wavelengths of light emitted by the first-type light-emitting unit, the second-type light-emitting unit, and the third-type light-emitting unit decrease sequentially;
the plurality of light-emitting units are arranged in rows and columns, at least one pixel unit comprises the first-type light-emitting unit, the second-type light-emitting unit, and the third-type light-emitting unit;
in a pixel unit, the first-type light-emitting unit and the second-type light-emitting unit are arranged in the same column, the first-type light-emitting unit and the second-type light-emitting unit are arranged in a same row as the third-type light-emitting unit;
in a column comprising the first-type light-emitting units, the first-type light-emitting units and the second-type light-emitting units are arranged alternately, columns comprising the first-type light-emitting units and the second-type light-emitting units and columns comprising the third-type light-emitting units are arranged alternately in a row direction;
a distance between an orthographic projection of an edge of the pixel opening corresponding to the light-emitting unit on the base plate and an orthographic projection of an edge of the isolation opening corresponding to the pixel opening on the base plate is referred to as a first distance, and the first distance corresponding to the first-type light-emitting unit, the first distance corresponding to the second-type light-emitting unit, and the first distance corresponding to the third-type light-emitting unit are all equal; and
the first ratio corresponding to the first-type light-emitting unit is less than the first ratio corresponding to the second-type light-emitting unit, and less than the first ratio corresponding to the third-type light-emitting unit.

14. The display panel according to claim 3, wherein the plurality of light-emitting units further comprise a third-type light-emitting unit, and areas of orthographic projections of the pixel openings corresponding to the first-type light-emitting unit, the second-type light-emitting unit, and the third-type light-emitting unit respectively, on the base plate, increase sequentially;
the first-type light-emitting units, the second-type light-emitting units, and the third-type light-emitting units are arranged in columns respectively, and columns comprising the first-type light-emitting units, columns comprising the second-type light-emitting units, and columns comprising the third-type light-emitting units are arranged sequentially and alternately;
a distance between an orthographic projection of an edge of the pixel opening corresponding to the light-emitting unit on the base plate and an orthographic projection of an edge of the isolation opening corresponding to the pixel opening on the base plate is referred to as a first distance, and the first distance corresponding to the first-type light-emitting unit. the first distance corresponding to the second-type light-emitting unit, and the first distance corresponding to the third-type light-emitting unit are all equal; and
the first ratio corresponding to the first-type light-emitting unit is less than the first ratio corresponding to the second-type light-emitting unit, and less than the first ratio corresponding to the third-type light-emitting unit.

15. The display panel according to claim 1, wherein the isolation structure comprises a support portion and a crown portion located on a side, facing away from the base plate, of the support portion, an orthographic projection of the support portion on the base plate is located within an orthographic projection of the crown portion on the base plate; and
an edge of an orthographic projection of an opening formed by the crown portion on the base plate is an edge of an orthographic projection of the isolation opening on the base plate;
the light-emitting unit comprises a first electrode, a light-emitting function layer, and a second electrode sequentially stacked on the base plate, and the light-emitting function layer and the second electrode of the light-emitting unit are located within the isolation opening corresponding to the light-emitting unit;
the support portion is a conductive structure, and the second electrode of the light-emitting unit is connected to the support portion; and
the display panel further comprises a first encapsulation layer, the first encapsulation layer comprises a plurality of encapsulation units corresponding to the plurality of isolation openings in one-to-one correspondence, and an encapsulation unit covers the isolation opening corresponding to the encapsulation unit.

16. A display panel, comprising:
a base plate;
a pixel defining layer disposed on a side of the base plate and provided with a plurality of pixel openings;
an isolation structure disposed on a side, facing away from the base plate, of the pixel defining layer, and defining a plurality of isolation openings respectively in communication with the corresponding pixel openings;
a plurality of light-emitting units comprising a first-color light-emitting unit and a second-type light-emitting unit, at least part of a light-emitting unit is located in the isolation opening;
wherein an area of the pixel opening corresponding to the first-color light-emitting unit is smaller than an area of the pixel opening corresponding to the second-color light-emitting unit; and
a ratio of an area of an orthographic projection of the pixel opening corresponding to the first-color light-emitting unit on the base plate to an area of an orthographic projection of the isolation opening corresponding to the first-color light-emitting unit on the base plate is less than a ratio of an area of an orthographic projection of the pixel opening corresponding to the second-color light-emitting unit on the base plate to an area of an orthographic projection of the isolation opening corresponding to the second-color light-emitting unit on the base plate.

17. The display panel according to claim 16, wherein the plurality of light-emitting units further comprise a third-color light-emitting unit, and the area of the pixel opening corresponding to the second-color light-emitting unit is smaller than an area of the pixel opening corresponding to the third-color light-emitting unit, and
the ratio of the area of the orthographic projection of the pixel opening corresponding to the second-color light-emitting unit on the base plate to the area of the orthographic projection of the isolation opening corresponding to the second-color light-emitting unit on the base plate is less than a ratio of an area of an orthographic projection of the pixel opening corresponding to the third-color light-emitting unit on the base plate to an area of an orthographic projection of the isolation opening corresponding to the third-color light-emitting unit on the base plate.

18. A display panel, comprising:
a base plate;
a pixel defining layer disposed on a side of the base plate and provided with a plurality of pixel openings;
an isolation structure disposed on a side, facing away from the base plate, of the pixel defining layer, and defining a plurality of isolation openings respectively in communication with corresponding pixel openings;
a plurality of light-emitting units comprising a first-type light-emitting unit and a second-type light-emitting unit, at least part of the light-emitting unit being located in the isolation opening;
wherein a perimeter of an orthographic projection of the pixel opening corresponding to the light-emitting unit on the base plate is less than a perimeter of an orthographic projection of the isolation opening corresponding to the light-emitting unit on the base plate, and a ratio of the perimeter of the orthographic projection of the pixel opening corresponding to the light-emitting unit on the base plate to the perimeter of the orthographic projection of the corresponding isolation opening on the base plate is referred to as a second ratio; and
the second ratio corresponding to the first-type light-emitting unit is less than the second ratio corresponding to the second-type light-emitting unit.

19. The display panel according to claim 18, wherein a perimeter of an orthographic projection of the pixel opening corresponding to the first-type light-emitting unit on the base plate is less than a perimeter of an orthographic projection of the isolation opening corresponding to the second-type light-emitting unit on the base plate.

20. The display panel according to claim 19, wherein the plurality of light-emitting units further comprise a third-color light-emitting unit, the perimeter of the orthographic projection of the pixel opening corresponding to the second-type light-emitting unit is less than a perimeter of an orthographic projection of the pixel opening corresponding to the third-type light-emitting unit, and the second ratio corresponding to the second-type light-emitting unit is less than the second ratio corresponding to the third-type light-emitting unit.
